(19) United States
(12) Patent Application Publication
(10) Pub. No.: US 2024/0203962 A1
(43) Pub. Date: Jun. 20, 2024

(54) ELECTRONIC DEVICE

(71) Applicant: Commissariat à l'Énergie Atomique et aux Énergies Alternatives, Paris (FR)

(72) Inventors: Cyrille Laviron, Grenoble Cedex 9 (FR); Cécilia Dupre, Grenoble Cedex 9 (FR); Aude Lefevre, Grenoble Cedex 9 (FR); Yann Lamy, Grenoble Cedex 9 (FR)

(73) Assignee: Commissariat à l'Énergie Atomique et aux Énergies Alternatives, Paris (FR)

(21) Appl. No.: 18/544,012

(22) Filed: Dec. 18, 2023

(30) Foreign Application Priority Data
Dec. 19, 2022 (FR) 2213881

(51) Int. Cl. H01L 25/16; H01L 23/00

(52) U.S. Cl. CPC H01L 25/16; H01L 24/08; H01L 24/80; H01L 28/60; H01L 2224/08265; H01L 2224/80006; H01L 2224/80357; H01L 2224/80896; H01L 2924/19041; H01L 2924/19104

(57) ABSTRACT

A device including first and second chips, the first chip including an electronic circuit and the second chip including a capacitor having a density greater than 700 nF/mm\hat{ }2, the first and second chips being bonded to each other by molecular bonding.

This application claims priority to French application number 2213881, filed Dec. 19, 2022, the contents of which is incorporated herein by reference in its entirety.

### TECHNICAL FIELD

The present disclosure generally concerns electronic devices and their manufacturing methods.

### PRIOR ART

There is a need to place capacitors close to electronic circuits, to optimize the supply of power to the electronic circuits. In particular, there is a need to significantly decrease equivalent stray inductances (ESL) and equivalent stray resistances (ESR), to greatly increase the efficiency of circuits. Conventionally, the connection of the capacitors, for example, discrete, to an active chip is performed by wire connection or by metal balls having dimensions in the range from 100 μm to 1 mm. These connections themselves generate stray inductances (from 5 to 100 pH) and/or resistances (20-100 mOhms). These stray inductances or resistances are equivalent to or even exceed the stray inductances or resistances of ultra-high-performance capacitors (1 μF/mm2).

### SUMMARY OF THE INVENTION

There exists a need for very narrows interconnections of ultra-high-performance capacitors, that is, having a high value and low ESR and ESL values, with active devices, for example, transistors, which are increasingly integrated and sensitive to the quality of the power and current supply. Conventional solutions of transfer of capacitive elements onto printed circuits or into packages no longer address this need, which requires a very dense integration, as close as possible to the transistors, and thus very high connection densities.

An embodiment overcomes all or part of the disadvantages of known methods of manufacturing chips comprising capacitors.

An embodiment provides a device comprising first and second chips, the first chip comprising an electronic circuit and the second chip comprising a capacitor having a density greater than 700 nF/mm\hat{ }2, the first and second chips being bonded to each other by molecular bonding.

Another embodiment provides a method comprising the forming of a first chip comprising an electronic circuit, and the forming of a second chip comprising a capacitor having a density greater than 700 nF/mm\hat{ }2, the method further comprising the bonding of the first and second chips by molecular bonding.

According to an embodiment, the first chip comprises an interconnection network and a semiconductor substrate inside and on top of which components of the electronic circuit are located.

According to an embodiment, the capacitor comprises a stack of a first insulating layer between two second conductive layers, the stack being located in a first anodized metal region.

According to an embodiment, the second chip comprises a third insulating layer having a first planar surface and a second surface, the second surface being covered with a fourth layer comprising at least the first region.

According to an embodiment, the first region is surrounded with a fourth insulating anodized metal region.

According to an embodiment, the method comprises the forming, on a support, of the third insulating layer and an of an anodizable metal layer.

According to an embodiment, the fourth layer of the second chip comprises second insulating anodized metal regions and third metal regions, the third regions being separated by second regions.

According to an embodiment, the method comprises the anodizing of the metal layer at the locations of the first and second regions.

According to an embodiment, the method comprises the bonding of the first chip to a handle and the removing of the support to expose the planar surface of the third layer.

According to an embodiment, the first and second chips are bonded by hybrid molecular bonding, the third insulating layer and the interconnection network comprising first conductive tracks located in contact with one another.

According to an embodiment, the surface of the substrate opposite to the interconnection network is covered with a fifth insulating layer and second conductive tracks, the fifth layer and the second conductive tracks being configured to be bonded to the third layer and to the first tracks by molecular bonding.

According to an embodiment, the chips are bonded by oxide-to-oxide molecular bonding, the device comprising vias extending in the first and second chips, crossing the third layer, and reaching a conductive track buried in the interconnection network.

According to an embodiment, the vias are formed after the bonding of the first and second chips.

According to an embodiment, each of the terminals of the capacitor is coupled to a third region.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows an implementation mode of a method of manufacturing a device comprising a capacitor close to an electronic circuit;

FIG. 2 shows an embodiment of a device comprising a capacitor close to an electronic circuit;

FIG. 3 shows a step of an implementation mode of the method of FIG. 1;

FIG. 4 shows another step of an implementation mode of the method of FIG. 1;

FIG. 5 shows another step of an implementation mode of the method of FIG. 1;

FIG. 6 shows another step of an implementation mode of the method of FIG. 1;

FIG. 7 shows another step of an implementation mode of the method of FIG. 1;

FIG. 8 shows another step of an implementation mode of the method of FIG. 1;

FIG. 9 shows an embodiment of a device comprising a capacitor close to an electronic circuit resulting from another implementation mode; and

FIG. 10 shows an embodiment of a device comprising a capacitor close to an electronic circuit resulting from another implementation mode.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

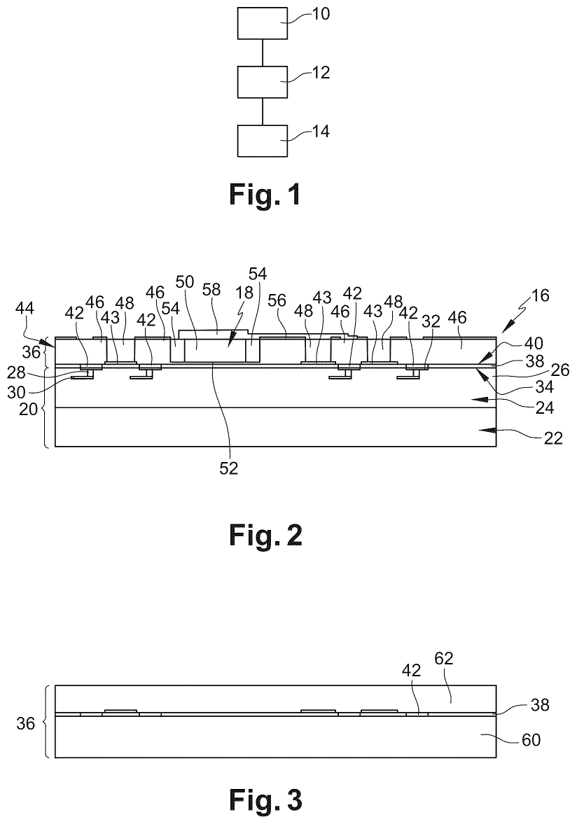

FIG. 1 schematically shows an implementation mode of a method of manufacturing a device comprising a capacitor close to an electronic circuit.

The method comprises a step 10 during which a first chip is formed. The first chip comprises an electronic circuit. The first chip for example comprises transistors. The first chip preferably comprises a semiconductor substrate, inside and on top of which are formed transistors, and an interconnection network. The interconnection network for example comprises insulating layers and a network of conductive tracks and of conductive vias. The first chip comprises a planar surface adapted to molecular bonding.

The method comprises a step 12 during which a second chip is formed. The second chip comprises at least one metal-insulator-metal capacitor, that is, a capacitor comprising a stack of an insulating layer and of two metal layers, the insulating layer being located between the metal layers. The capacitor stack is located on a metal layer comprising at least one anodized region. Said region of the metal layer comprises a plurality of cavities, or nanopores, the stack forming the capacitor extending over the walls and the bottom of the cavities and over the portions of the layer between the cavities.

Preferably, the second chip comprises no other active electronic components than capacitors, and possibly resistors. For example, the second chip comprises no transistor. For example, the second chip comprises no semiconductor substrate.

The second chip comprises a planar surface, adapted to molecular bonding.

Steps 10 and 12 may be carried out independently, for example successively or in parallel.

The method further comprises a step 14 during which the first and second chips are bonded to each other by molecular bonding. More specifically, the planar surfaces of the first and second chips are bonded to each other by molecular bonding.

FIG. 2 shows an embodiment of a device 16 comprising a capacitor 18, and possibly resistors, not shown, close to an electronic circuit. Device 16 is obtained by a method such as that described in relation with FIG. 1.

Device 16 comprises a chip 20. Chip 20, like the first chip of FIG. 1, comprises a semiconductor substrate 22. Electronic components, such as transistors, are located inside and on top of substrate 22. Chip 20 further comprises an interconnection network 24. Interconnection network 24 comprises insulating layers 26, the separations of the different layers not being shown in FIG. 2. Interconnection network 24 further comprises conductive vias 28 and conductive tracks 30. Network 24 comprises metal tracks 32 flush with a surface 34 of network 24. Surface 34 is the surface most distant from substrate 22, in other words the surface opposite to the surface of network 24 in contact with substrate 22. Tracks 32 are adapted to a hybrid molecular bonding step.

Vias 28 and tracks 30, 32 enable to form electric connections between electronic components of chip 20 and other components of chip 20 or components external to the chip, for example capacitor 18.

Device 16 also comprises a chip 36. Chip 36 corresponds to the second chip of FIG. 1. Chip 36 comprises a capacitor 18, and optionally resistors. Although a single capacitor 18 is shown in FIG. 2, chip 36 may comprise a plurality of capacitors 18.

Chip 36 comprises an insulating layer 38. Layer 38 has, for example, a thickness in the range from 10 nm to 1 μm. Insulating layer 38 comprises a surface 40. Chip 36 further comprises metal tracks 42 in layer 38. Metal tracks 42 are flush with surface 40 of layer 38. Preferably, tracks 42 run through track 38. In other words, tracks 42 preferably have the same thickness as layer 38. Surface 40 of layer 38 is bonded by hybrid molecular bonding to surface 34 of chip 20. Thus, each track 42 is preferably located in such a way as to be in contact with a track 32. Connections between chip 20 and chip 36 are thus formed via tracks 32 and 42.

Chip 36 further comprises elements 43 made of insulating material, for example of the same material as layer 38. Elements 43 are located on layer 38, more precisely on the surface opposite to surface 40. Elements 43 preferably do not cover, even partially, tracks 42. Elements 43 cover certain portions of layer 38. Elements 43 do not fully cover layer 38. Elements 43 for example have a thickness in the range from 300 nm to 3 μm.

Chip 36 comprises a layer 44. Layer 44 is located on layer 38, on tracks 42, and on elements 43. More precisely, layer 44 covers the surface opposite to surface 40 of layer 38. Layer 44 for example has a thickness lower than 20 μm, for example, substantially equal to 10 μm.

Layer 44 comprises regions 46. Regions 46 are conductive regions. Regions 46 are made of an anodizable conductive material, preferably of metal. Regions 46 are for example made of aluminum or of tantalum. Each track 42 is preferably covered, preferably in contact, with a region 46.

Regions 46 extend, at least in certain portions of layer 44, along the entire height of layer 44. Regions 46 thus extend from the upper surface of layer 20 to the upper surface of layer 44. Each region 46 enables to continue the electric link of the track 42 having region 46 in contact therewith.

Regions 46 are for example surrounded with regions 48 of layer 44. Regions 48 are insulating regions. Regions 48 are made of the material of regions 46, for example of aluminum, which has been anodized, for example to obtain alumina. Regions 48 are thus porous regions. In other words, regions 48 comprise a plurality of cavities, or nanopores, not shown, extending, for example, along the entire height of region 48.

Regions 48 are located on elements 43. Preferably, each element 43 is at least partially, for example predominantly, covered with a region 48. Preferably, each region 48 covers an element 43. Elements 43 and regions 48 enable to form a lateral insulation in layer 44.

Layer 44 further comprises one or a plurality of regions 50, having capacitors 18 located therein. Each region 50 for example comprises a single capacitor 18. In the example of FIG. 2, layer 44 comprises a single capacitor 18, and a single region 50. Capacitor 18 is a high-density capacitor, that is, a capacitor having a density greater than 700 nF/mm\hat{ }2, for example greater than 1 μF/mm\hat{ }2.

Region 50 extends in front of a portion of layer 38 not covered with elements 43. Thus, region 50 does not face, even partially, an element 43. Region 50 extends from the upper surface of layer 44, that is, the surface most distant from layer 38. Region 50 is thus flush with the upper face of layer 44. Region 50 for example does not extend all the way to layer 38. Preferably, the height of region 50 is substantially equal to the height of the portions of regions 46 located in contact with elements 43. Thus, region 50 is separated from layer 38, for example, by a distance substantially equal to the height of regions 43. Preferably, region 50 is separated from layer 38 by a conductive portion 52, for example a layer of aluminum or of an alloy comprising aluminum covered with a tungsten layer forming a stop layer for the anodization of region 50.

Region 50 is, like regions 48, made of the material of regions 46, for example of aluminum, which has been anodized, for example to obtain alumina. Region 50 thus comprises a plurality of cavities, not shown, for example extending along the entire height of region 50. The density of cavities in region 50 is for example greater than 40 cavities/μm\hat{ }2.

Capacitor 18 is a metal-insulator-metal or MIM capacitor. Capacitor 18 comprises a stack of layers, not shown in FIG. 1, of an insulating layer located between two conductive layers, preferably made of metal. The stack of layers of capacitor 18 is conformally located on the porous structure of region 50.

A lower layer of the stack of capacitor 18, that is, one of the conductive layers, preferably a metal layer, extends conformally over the porous structure, and in particular in the cavities of region 50. The lower layer of a capacitor 18 covers, preferably entirely, the upper surface of region 50, the side walls of the cavities, and the bottom of the cavities. The lower layer of a capacitor 18 is thus in contact with portion 52.

An intermediate layer of the stack of capacitor 18, that is, the insulating layer, extends conformally over the lower layer. The intermediate layer extends inside of the cavities. The intermediate layer preferably fully covers the lower layer.

An upper layer of the stack of a capacitor 18, that is, the other conductive layer, for example made of metal, extends conformally over the intermediate layer. The upper layer extends in the cavities. The upper layer for example fills the cavities. The upper layer preferably fully covers the intermediate layer. The upper layer for example comprises a planar upper face extending over the upper surface of the porous structure.

The layer 44 for example comprises one or a plurality of insulating regions 54 delimiting region 50. Region 50 is surrounded with regions 54. Region 50 is thus laterally insulated from the rest of layer 44. Region 50 is preferably directly in lateral contact with regions 54. Thus, region 50 is preferably not separated from regions 54 by other regions of layer 44. In particular, region 50 is preferably not separated from regions 54 by regions of the material of region 46 which has not been anodized and which is not porous.

Regions 54 are insulating regions. Regions 54 are made of the material of layer 44, for example of aluminum which has been anodized, for example of alumina. Regions 54 are thus porous regions. In other words, regions 54 comprise a plurality of cavities, not shown, extending, for example, along the entire height of region 54. Preferably, the height of regions 54 is substantially equal to the height of the region 50. Regions 54 extend from the upper surface of layer 44, that is, the surface most distant from layer 38. Regions 54 are thus flush with the upper surface of layer 44. Regions 54 for example do not extend all the way to layer 38. Regions 54 are preferably separated from layer 38 by conductive portion 52.

Chip 36 further comprises insulating portions 56. Insulating portions 56 partially cover the upper surface of layer 44. Chip 36 further comprises a conductive track 58 located on the upper surface of layer 44 and of certain portions 56. In particular, track 58 extends over the upper surface of region 50, and more precisely over the upper layer of the stack of capacitor 18. Preferably, track 58 fully covers the upper surface of the upper layer of the stack. Track 58 allows the connection between an electrode of capacitor 18 and external elements.

The portion 52 of a region 46, in contact with the bottom layer of the capacitor, allows the connection between another electrode of the capacitor and elements external to the chip. The region 46 comprising portion 52 extends, for example, around regions 50 and 54. The region 46 comprising portion 52 is in contact with a track 42.

Track 58 is electrically coupled to, preferably in contact with, a region 46. For example, said region 46 is separated from capacitor 18 by a region 48, at least a portion of region 46 in contact with the lower layer of the stack, and a region 54. The regions 46 having track 58 extending in front of them are covered with portions 56. Thus, track 58 is entirely separated from the regions 46 having track 58 extending in front of them by one or a plurality of insulating portions 56.

FIGS. 3 to 8 illustrate steps, preferably successive, of an implementation mode of the method of FIG. 1. More precisely, FIGS. 3 to 8 illustrate steps, preferably successive, of an implementation mode of a method of manufacturing the device of FIG. 2.

FIG. 3 shows a step of an embodiment of the method of FIG. 1. More precisely, FIG. 3 shows a step of manufacturing of chip 36.

During this step, layer 38 is formed on a support 60, more precisely on an upper surface of support 60. Layer 38 is made of an insulating material, for example of silicon oxide. Layer 38 preferably covers, during its forming, the entire upper surface of support 60.

Support 60 is, for example, a semiconductor substrate. Support 60 is for example made of a material selectively etchable over the materials of layer 38 and of tracks 42. The upper surface of support 60 is preferably planar.

The step of FIG. 3 further comprises the forming of tracks 42 in layer 38. For example, cavities crossing layer 38, that is, reaching support 60, are formed in layer 38 at the locations of tracks 42 and are filled with the material of tracks 42.

The step of FIG. 3 also includes the forming of elements 43. Elements 43 are made of an insulating material, preferably of the same material as layer 38. For example, elements 43 are formed on the upper surface of layer 38.

The step of FIG. 3 further comprises the forming of a layer 62 made of an anodizable conductive material, preferably of metal. Layer 62 is for example made of aluminum or of tantalum. Layer 62 is made of the material of regions 46.

Preferably, layer 62 preferably comprises no cavities during its deposition. Preferably, the lower and upper surfaces of layer 62, that is, the layer closest to layer 38 and the layer most distant from layer 38, are planar and parallel. Layer 62 is for example made of aluminum.

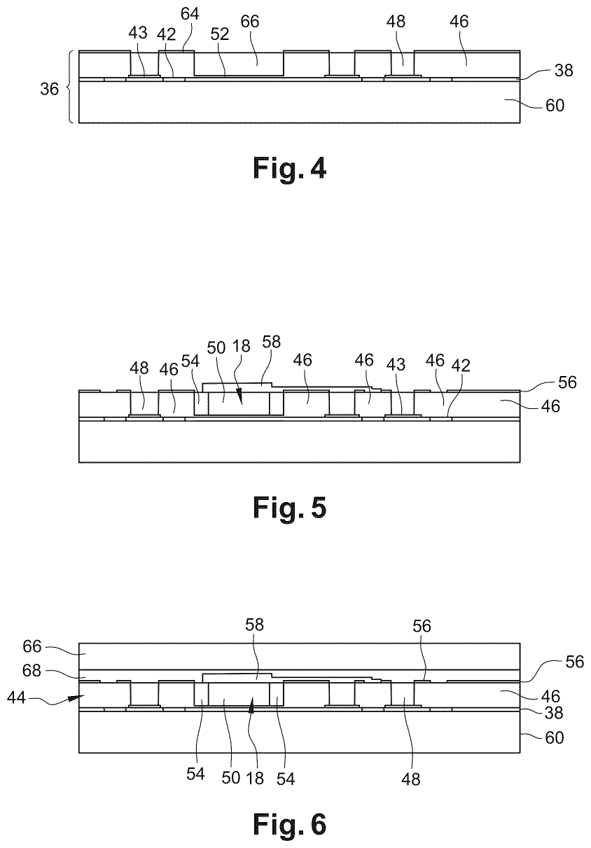

FIG. 4 shows another step of an implementation mode of the method of FIG. 1.

During this step, a mask 64 is formed on the upper surface of layer 62. Mask 64 is for example made of the same material as portions 56. Mask 64 comprises openings in front of the locations of regions 48, 50, and 54.

The step of FIG. 4 further comprises the forming of nanopores at the locations of regions 48, 50, and 54. More precisely, the step in FIG. 4 for example comprises the forming of nanopores to form regions 48 and a region 68 corresponding to the locations of regions 50 and 54. For clarity, the nanopores are not shown.

To form nanopores in regions 48 and 68, the portions of layer 62 corresponding to regions 48 and 68 are submitted to an anode oxidation process, enabling to form a nanostructured insulating layer.

Anodizing, or anodic oxidation, is a wet electrolytic process. The principle is based on the application of an imposed potential difference between two conductive electrodes immersed in an electrolytic solution, which may for example be acidic. In the example of the method of FIGS. 3 to 8, one of the conductive electrodes, for example the anode, is layer 62. The application of a potential to an electrode induces a growth of alumina on its surface if the electrode is made of aluminum. The dissolving of the aluminum electrode in the acid bath causes the appearing of nanopores or of cavities in the electrode surface.

The nanopores for example advantageously have a diameter in the order of 80 nm and are spaced apart by 50 nm. The nanopore density is for example 40 cavities/μm². Further, the anodization process used enables to obtain nanopores emerging onto layer 62. In other words, nanopores can be considered as nano-cylinders, having a side emerging onto layer 52.

The nanopore forming method is carried out in such a way that the nanopores reach elements 43 in regions 48 and do not reach layer 38 in region 68. Thus, portion 52 is formed under region 68.

FIG. 5 shows another step of an implementation mode of the method of FIG. 1.

The method of FIG. 5 comprises the forming of the stack of layers of capacitor 18. More specifically, capacitor 18 comprises a stack of a lower metal layer, of an insulating layer, and of an upper metal layer conformally formed in region 50, as described in relation with FIG. 2.

Thus, the lower layer of the stack of capacitor 18 extends conformally over the nanopore structure, and in particular inside of the nanopores of region 50. The lower layer of capacitor 18 covers in region 50, preferably fully, the upper surface of layer 44, the side walls of the nanopores, and the bottom of the nanopores. The lower layer of capacitor 18 is thus flush with the upper surface of portion 52. The lower layer of the capacitor 18 is thus electrically coupled, preferably in contact, with a region 46 via the portion 52 located under capacitor 18.

The intermediate layer of the stack of capacitor 18 extends conformally over the lower layer. The intermediate layer extends inside of the nanopores. The intermediate layer preferably fully covers the lower layer.

The upper layer of the stack of capacitor 18 extends conformally over the intermediate layer. The upper layer extends inside of the nanopores. The upper layer for example fills the nanopores. The upper layer preferably fully covers the intermediate layer. The upper layer comprises, for example, a planar upper surface extending above the upper surface of the nanopore structure in region 50.

The step shown in FIG. 5 further comprises the forming of the portions of insulating material 56. Portions 56 are, for example, obtained from mask 64, for example by etching openings at the locations where portions 56 are not present. Alternatively, mask 64 may be removed and replaced with portions 56.

The step of FIG. 5 also comprises the forming of track 58.

FIG. 6 shows another step of an implementation mode of the method of FIG. 1.

During this step, a handle 66 is bonded to chip 36. Handle 66 is bonded to the upper surface of chip 36, that is, the surface opposite to support 60.

Handle 66 is bonded to chip 36 by a layer of bonding material, for example a temporary glue layer 68. Temporary glue layer 68 is located on the upper surface of chip 36. More precisely, temporary glue layer 68 is formed in such a way as to cover the entire upper surface of chip 36. The upper surfaces of track 58, of portions 56, and of layer 44 are covered with temporary glue layer 68.

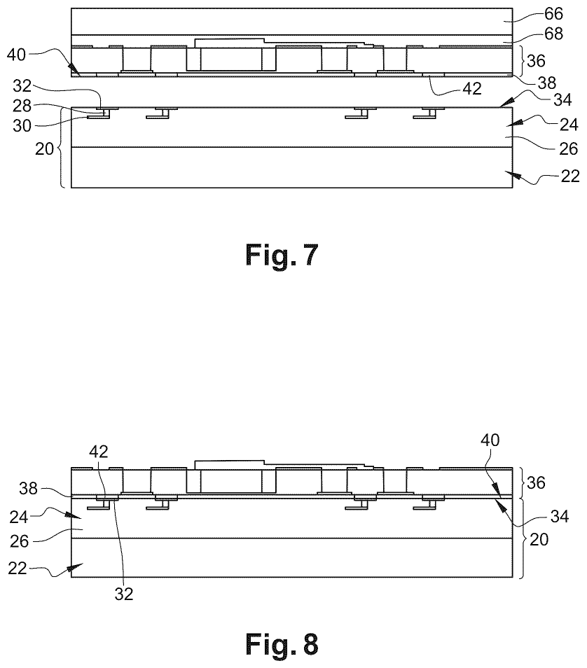

FIG. 7 shows another step of an implementation mode of the method of FIG. 1.

During this step, support 60 is removed, for example by a grinding step, for example, coarse and then fine, followed by chemical etching.

The step shown in FIG. 7 also comprises the forming of chip 20. The forming of chip 20 may be carried out parallel or successively to the forming of chip 36. Thus, chip 20 is formed independently from the forming of chip 36.

The forming of chip 20 corresponds, for example, to the forming of an integrated circuit chip.

The forming of chip 20 comprises the forming of electronic components, for example of an electronic circuit, in substrate 22. The forming of chip 20 comprises, for example, the forming of transistors in substrate 22.

The forming of chip 20 further comprises the forming of an interconnection network 24. The forming of the interconnection network comprises the forming of insulating layers 26, and the forming in layers 26 of a network of conductive tracks 30 and of conductive vias 28.

The forming of interconnection network 24 further comprises the forming, at the upper surface 34 of chip 20, that is, the surface of the interconnection network most distant from substrate 22, of tracks 32 flush with the upper surface of network 24. The upper surface of network 24 is a planar surface, adapted to molecular bonding.

FIG. 8 shows another step of an implementation mode of the method of FIG. 1.

During this step, chips 20 and 36 are bonded to each other by hybrid molecular bonding, via planar surfaces 34 and 40. Thus, tracks 32 and 42 are placed into contact, and the upper layer 26 of the stack of network 24 is placed into contact with the lower surface of layer 38. Preferably, each track 32 is placed into contact with a track 42.

The molecular bonding of chips 20 and 36 comprises an anneal step, for example below 450° C., for example substantially equal to 400° C.

Further, the step of FIG. 8 comprises the removing of handle 66 and of bonding layer 68. The removing of handle 66 and of bonding layer 68 may be performed before or after the anneal step, according to the composition and the thermal budget of the glue.

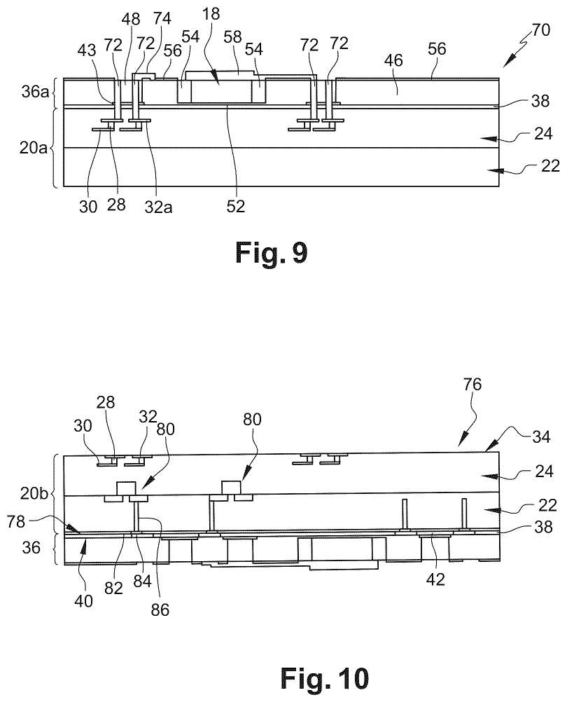

FIG. 9 shows an embodiment of another device 70 comprising a capacitor close to an electronic circuit resulting from another implementation mode.

The device 70 of FIG. 9 comprises elements identical to the device 16 of FIG. 2, which will not be described again in detail. In particular, device 70 comprises:
a chip 20a, comprising substrate 22 inside and on top of which electronic components and interconnection network 24 are formed;
chip 36a, comprising insulating layer 38, regions 48, 50, 54, capacitor 18, portions 56, and track 58.

Device 70 differs from the device 16 of FIG. 2 in that, in device 70, chips 36a and 20a are bonded to each other by oxide-to-oxide bonding and not by hybrid bonding.

Thus, chip 20a differs from the chip 20 of FIG. 2 in that the upper surface of chip 20a, that is, the upper surface of network 24, that is, the surface of chip 20a most distant from substrate 22, is adapted to oxide-to-oxide molecular bonding. Thus, the upper insulating layer 26 of network 24, that is, the layer 26 most distant from the substrate, comprises no tracks 42.

Thus, during the manufacturing of chip 20a, that is, before the molecular bonding step of chips 20a and 36a, the upper surface of chip 20a is entirely formed of oxide, that is, the material of layer 26.

Further, chip 36a differs from the chip 36 of FIG. 2 in that layer 38 comprises no tracks 42. Further, portions 56 for example cover all the regions 46.

Thus, during the manufacturing of chip 36a, that is, before the step of molecular bonding of chips 20a and 36a, the lower surface of chip 20a, that is, the lower surface of layer 38, is entirely formed of oxide, that is, the material of layer 38.

Device 70 comprises conductive vias 72. Vias 72 extend from chip 20a to chip 36a. More precisely, each via 72 extends, for example, from a conductive track 32a buried in network 24. One end of each via 72 is, for example, in contact with the upper surface of a track 32a. Each via 72 preferably extends all the way to the upper surface of chip 36a. Preferably, each via 72 crosses layer 38 and an element 43. Preferably, each via 72 at least partially, preferably entirely, crosses a region 48. Each via 72 is thus separated from regions 46 and from the other vias 72 by layer 38, elements 43, and regions 48. Vias 72 are connected to one another, to capacitors 18, or to elements external to device 70 by conductive elements. In particular, a via 72 is coupled to track 58. In other words, a portion of track 58 extends all the way to, and is in contact with, the upper end of a via 72, that is, the end flush with the upper surface of region 48, that is, the end opposite to the end located in chip 20a in contact with tracks 32a. A first terminal of capacitor 18 is thus coupled to a circuit of chip 20 via track 58, a via 72, and interconnection network 24.

Another via 72, comprising an end flush with the upper surface of a region 48, is coupled, for example by a conductive track 74 extending over the upper surface of chip 36a, to the region 46 comprising portion 52, that is, the region 56 coupled to a second terminal of capacitor 18. In other words, track 74, for example a metal track, is for example in contact with the end of via 72 and with the upper surface of the region 46 comprising portion 52. Track 74 preferably runs through the portion 56 extending above the region 46 comprising portion 52. In the case where track 74 extends over other regions 46, track 74 is preferably separated from the other regions 46 by a portion 56.

Vias 72 are preferably formed after the molecular bonding step. Upper layer 26 and layer 38 preferably comprise no metal track, except for vias 72. Thus, once chips 20a and 36a have been bonded to each other, cavities are formed from the upper surface of chip 36a, to reach tracks 32a, and then filled with conductive material.

FIG. 10 shows an embodiment of a device 76 comprising a capacitor close to an electronic circuit resulting from another implementation mode.

The device 76 of FIG. 10 comprises elements identical to the device 16 of FIG. 2, which will not be described again in detail. In particular, device 76 comprises:
the chip 36 such as described in relation with FIG. 2; and
a chip 20b comprising interconnection network 24 and substrate 22.

Device 76 differs from device 16 in that chip 36 is not bonded to the upper surface 34 of chip 20b, that is, the upper surface 34 of interconnection network 24, but to a lower surface 78 of chip 20b, that is, the surface opposite to surface 34 of chip 20b. In other words, chips 20b and 36 are bonded to each other by hybrid molecular bonding between surfaces 40 and 78.

Chip 20b comprises, like chip 20, active electronic components. Chip 20b comprises, for example, transistors 80 schematically shown in FIG. 10. Transistors 80 are located inside and on top of substrate 22. Thus, transistors 80 comprise regions in substrate 22, for example source and drain regions. Transistors 80 comprise, for example, a control terminal located on the substrate, for example on the upper surface of the substrate, that is, in the insulating layers 26 of the interconnection network.

Surface 78 of chip 20b is adapted to a hybrid molecular bonding, for example metal-oxide. Chip 20b comprises a layer 82 of an insulating material, for example, of silicon oxide, covering the lower surface of substrate 22, that is, the surface of substrate 22 most distant from surface 34. Chip 20b comprises tracks 84 in layer 82. Tracks 84 are flush with surface 78. Tracks 84 are located in such a way as to be in contact with tracks 42, to allow the molecular bonding and the electric coupling with chip 36.

Chip 20b comprises vias 86 extending from tracks 84 to the electronic components of chip 20b. Vias 86 are, for example, insulated conductive vias, that is, vias comprising a conductive core and an insulating sheath.

Chip 20b comprises, like the chip 20 of FIG. 2, conductive tracks 30 buried in network 24, conductive vias 28, and tracks 32 flush with surface 34 of chip 20b. Thus, chip 20b is coupled by its lower surface 78 to capacitor 18, and may be connected, via interconnection network 24, to other elements external to the chip.

In other embodiments, the transistors 80 may be replaced with other types of transistors.

An advantage of the embodiments described in detail is that it is possible to form capacitors very close to chips comprising electronic circuits, only separated, for example, by a metallization level.

Another advantage of the described embodiments is that the manufacturing of the capacitors does not risk causing damage to the electronic circuits. In particular, the electronic circuits are not subjected to the thermal budget of the forming of the capacitor, but only to that of the bonding of the two chips.

Various embodiments and variants have been described. Those skilled in the art will understand that certain features of these various embodiments and variants may be combined, and other variants will occur to those skilled in the art. In particular, although the described steps of the method refer to chips, the steps may be implemented on a silicon wafer to simultaneously form a large number of chips. Thus, the chips may be manufactured individually and bonded to one another. According to another embodiment, a plurality of chips are simultaneously formed in semiconductor wafers. The chips are then individualized and bonded to one another.

Finally, the practical implementation of the described embodiments and variants is within the abilities of those skilled in the art based on the functional indications given hereabove.

What is claimed is:

1. Device comprising first and second chips, the first chip comprising an electronic circuit and the second chip comprising a capacitor having a density greater than 700 nF/mm\hat{ }2, the first and second chips being bonded to each other by molecular bonding, wherein the capacitor comprises a stack of a first insulating layer between two second conductive layers, the stack being located in a first anodized metal region.

2. Device according to claim 1, wherein the first chip comprises an interconnection network and a semiconductor substrate inside and on top of which components of the electronic circuit are located.

3. Device according to claim 1, wherein the second chip comprises a third insulating layer having a first planar surface and a second surface, the second surface being covered with a fourth layer comprising at least the first region.

4. Device according to claim 3, wherein the first region is surrounded with a fourth insulating anodized metal region.

5. Device according to claim 3, wherein the fourth layer of the second chip comprises second insulating anodized metal regions and third metal regions, the third regions being separated by second regions.

6. Device according to claim 3, wherein the first and second chips are bonded by hybrid molecular bonding, the third insulating layer and the interconnection network comprising first conductive tracks located in contact with one another.

7. Device according to claim 6, wherein the surface of the substrate opposite to the interconnection network is covered with a fifth insulating layer and second conductive tracks, the fifth layer and the second conductive tracks being configured to be bonded to the third layer and to the first tracks by molecular bonding.

8. Device according to claim 3, wherein the chips are bonded by oxide-to-oxide molecular bonding, the device comprising vias extending in the first and second chips, crossing the third layer and reaching a conductive track buried in the interconnection network.

9. Device according to claim 5, wherein each of the terminals of the capacitor is coupled to a third region.

10. Method comprising forming a first chip comprising an electronic circuit, and forming a second chip comprising a capacitor having a density greater than 700 nF/mm\hat{ }2, the method further comprising bonding of the first and second chips by molecular bonding, wherein the capacitor comprises a stack of a first insulating layer between two second conductive layers, the stack being located in a first anodized metal region.

11. Method according to claim 10, wherein the second chip comprises a third insulating layer having a first planar surface and a second surface, the second surface being covered with a fourth layer, comprising forming, on a support, of the third insulating layer and of an anodizable metal layer.

12. Method according to claim 11, wherein the fourth layer of the second chip comprises second insulating anodized metal regions and third metal regions, the third regions being separated by second regions, comprising anodizing of the metal layer at the locations of the first and second regions.

13. Method according to claim 12, wherein the second chip comprises a third insulating layer having a first planar surface and a second surface, the second surface being covered with a fourth layer comprising at least the first region, comprising bonding the first chip to a handle and removal of the support to expose the planar surface of the third layer.

14. Method according to claim 11, wherein the chips are bonded by oxide-to-oxide molecular bonding, the device comprising vias extending in the first and second chips, crossing the third layer and reaching a conductive track buried in the interconnection network, wherein the vias are formed after the bonding of the first and second chips.
